(19) United States
(12) Patent Application Publication
(10) Pub. No.: US 2024/0258226 A1
(43) Pub. Date: Aug. 1, 2024

(54) CHIP-ON-FILM AND DISPLAY DEVICE

(71) Applicant: WUHAN CHINA STAR OPTOELECTRONICS TECHNOLOGY CO., LTD., Wuhan (CN)

(72) Inventor: Fu LI, Wuhan (CN)

(21) Appl. No.: 18/466,278

(22) Filed: Sep. 13, 2023

(30) Foreign Application Priority Data
Jan. 31, 2023 (CN) 202310099633.1

(51) Int. Cl. H01L 23/498

(52) U.S. Cl. CPC H01L 23/49838; H01L 23/49811; H01L 23/4985; H01L 25/0753

(57) ABSTRACT

A chip-on-film includes a flexible substrate, a plurality of negative polarity pins, and a positive polarity pin. The plurality of negative polarity pins are arranged in a row in a first direction on the flexible substrate, and two adjacent negative polarity pins of the plurality of negative polarity pins are arranged in an interval. The positive polarity pin is disposed on the flexible substrate. The positive polarity pin is at least partially located between two adjacent negative polarity pins of the plurality of negative polarity pins. The positive polarity pin includes a first extension portion and a second extension portion. The first extension portion intersects the second extension portion.

### CROSS REFERENCE TO RELATED APPLICATION

This application claims priority to Chinese Application No. 202310099633.1, filed on Jan. 31, 2023. The entire disclosure of the above application is incorporated herein by reference.

### FIELD OF THE INVENTION

The present disclosure relates to a technical field of a display device, in particular to a chip-on-film and a display device.

### BACKGROUND

With the development of display technology, the resolution of display devices and other parameters continue to increase. Thus, the number of pixels that need to be driven by a light-emitting substrate also increase significantly, and the more chip-on-films (COFs) are required on the light-emitting substrate.

Currently, in the bonding process, the chip-on-films and the light-emitting substrate shift in the opposite direction due to the expansion and contraction of the material of the light-emitting substrate, such as expansion or contraction. Thus, the chip-on-film cannot be accurately aligned with the light-emitting substrate. Moreover, because a positive polarity pin is disposed between the negative polarity pins of each chip-on-film, if the alignment recognition between the positive polarity pin and negative polarity pin is limited, it may cause to a CCD (charge-coupled device) to fail recognize the positive and negative polarity of the pins on the chip-on-film. Therefore, when the alignment between the chip-on-films and the light-emitting substrate is not accurate, it is easy to cause a short circuit between the positive and negative polarity pins, which affects the bonding yield of the chip-on-films.

### SUMMARY

The present disclosure provides a chip-on-film and a display device to solve the problem of low bonding yield of the chip-on-film.

In one aspect, the present disclosure provides a chip-on-film. The chip-on-film includes a flexible substrate, a plurality of negative polarity pins, and a positive polarity pin. The plurality of negative polarity pins are arranged in a row in a first direction on the flexible substrate, and two adjacent negative polarity pins of the plurality of negative polarity pins are arranged in an interval. The positive polarity pin is disposed on the flexible substrate. The positive polarity pin is at least partially located between two adjacent negative polarity pins of the plurality of negative polarity pins. The positive polarity pin includes a first extension portion and a second extension portion. The first extension portion intersects the second extension portion.

Optionally, the first extension portion extends in the first direction, the second extension portion extends in a second direction, and the first direction is perpendicular to the second direction.

Optionally, the chip-on-film further includes two pin groups disposed along the first direction at an interval. Each of the pin groups includes multiple negative polarity pins of the plurality of negative polarity pins, and two adjacent negative polarity pins in each pin group are disposed along the first direction at an interval. The positive polarity pin is at least partially located between the two pin groups that are adjacent to each other. In the first direction, a distance between two adjacent negative polarity pins of the plurality of negative polarity pins is less than a distance between the two pin groups.

Optionally, both the first extension portion and the second extension portion are located between two adjacent negative polarity pins of the plurality of negative polarity pins.

Optionally, a middle portion of the first extension portion is connected with a middle portion of the second extension portion.

Optionally, the first extension portion is connected to one terminal of the second extension portion.

Optionally, the plurality of negative polarity pins are arranged in a plurality of rows, and the negative polarity pins in two adjacent rows of the plurality of rows are arranged at an interval to form an accommodation area. The first extension portion is located in the accommodation area, and the second extension is located between two adjacent negative polarity pins of the plurality of negative polarity pins.

Optionally, the number of positive polarity pins is at least two, the two positive polarity pins are disposed at an interval. Each of the positive polarity pins is located between two adjacent negative polarity pins of the plurality of negative polarity pins.

Optionally, a length of the first extension portion ranges from 0.5 mm to 5 mm, and a length of the second extension portion ranges from 0.7 mm to 1.5 mm.

In another aspect, the present disclosure provides a display device. The display device includes a light-emitting substrate and a chip-on-film. One terminal of the chip-on-film is bonded to the light-emitting substrate. The chip-on-film includes a flexible substrate, a plurality of negative polarity pins, and a positive polarity pin. The plurality of negative polarity pins are arranged in a row in a first direction on the flexible substrate, and two adjacent negative polarity pins of the plurality of negative polarity pins are arranged in an interval. The positive polarity pin is disposed on the flexible substrate. The positive polarity pin is at least partially located between two adjacent negative polarity pins of the plurality of negative polarity pins. The positive polarity pin includes a first extension portion and a second extension portion. The first extension portion intersects the second extension portion.

Optionally, the first extension portion extends in the first direction, the second extension portion extends in a second direction, and the first direction is perpendicular to the second direction.

Optionally, the chip-on-film further includes two pin groups disposed along the first direction at an interval. Each of the pin groups includes multiple negative polarity pins of the plurality of negative polarity pins, and two adjacent negative polarity pins in each pin group are disposed along the first direction at an interval. The positive polarity pin is at least partially located between the two pin groups that are adjacent to each other. In the first direction, a distance between two adjacent negative polarity pins of the plurality of negative polarity pins is less than a distance between the two pin groups.

Optionally, both the first extension portion and the second extension portion are located between two adjacent negative polarity pins of the plurality of negative polarity pins.

Optionally, a middle portion of the first extension portion is connected with a middle portion of the second extension portion.

Optionally, the first extension portion is connected to one terminal of the second extension portion.

Optionally, the plurality of negative polarity pins are arranged in a plurality of rows, and the negative polarity pins in two adjacent rows of the plurality of rows are arranged at an interval to form an accommodation area. The first extension portion is located in the accommodation area, and the second extension is located between two adjacent negative polarity pins of the plurality of negative polarity pins.

Optionally, the number of positive polarity pins is at least two, the two positive polarity pins are disposed at an interval. Each of the positive polarity pins is located between two adjacent negative polarity pins of the plurality of negative polarity pins.

Optionally, a length of the first extension portion ranges from 0.5 mm to 5 mm, and a length of the second extension portion ranges from 0.7 mm to 1.5 mm.

The chip-on-film and the display device of the present disclosure are provided with a plurality of negative polarity pins arranged in a row along a first direction on a flexible substrate and further with a positive polarity pin. The positive polarity pin is at least partially located between two adjacent negative polarity pins, and the positive polarity pin comprises a first extension portion and a second extension portion. The first extension portion intersects the second extension portion. Because the shape of the positive polarity pin is different from that of the negative polarity pins, the recognition accuracy to the positive polarity pin is improved. Accordingly, the alignment accuracy of the chip-on-film is improved, thereby preventing the short-circuit problem during bonding of the chip-on-film, which is conducive to improving the bonding yield of the chip-on-film.

### BRIEF DESCRIPTION OF THE DRAWINGS

In order to more clearly illustrate the technical solution in the embodiment of the present disclosure, the following will be a brief introduction to the drawings required in the description of the embodiment. Obviously, the drawings described below are only some embodiments of the present disclosure, for those skilled in the art, without the premise of creative labor, may also obtain other drawings according to these drawings.

FIG. 1 is a schematic structural diagram of a chip-on-film according to one embodiment of the present disclosure.

FIG. 2 is a schematic structural diagram of a chip-on-film according to another embodiment of the present disclosure.

FIG. 3 is a schematic structural diagram of a positive polarity pin in a chip-on-film according to another embodiment of the present disclosure.

FIG. 4 is a schematic structural diagram of a positive polarity pin in a chip-on-film according to another embodiment of the present disclosure.

FIG. 5 is a schematic structural diagram of a positive polarity pin in a chip-on-film according to another embodiment of the present disclosure.

FIG. 6 is a schematic diagram of a front structure of a light-emitting substrate according to an embodiment of the present disclosure.

FIG. 7 is a schematic diagram of a back structure of a light-emitting substrate according to an embodiment of the present disclosure.

### DETAILED DESCRIPTION OF PREFERRED EMBODIMENTS

To help a person skilled in the art better understand the solutions of the present disclosure, the following clearly and completely describes the technical solutions in the embodiments of the present invention with reference to the accompanying drawings in the embodiments of the present invention. Apparently, the described embodiments are a part rather than all of the embodiments of the present invention. All other embodiments obtained by a person of ordinary skill in the art based on the embodiments of the present invention without creative efforts shall fall within the protection scope of the present disclosure.

The term “first”, “second” are for illustrative purposes only and are not to be construed as indicating or imposing a relative importance or implicitly indicating the number of technical features indicated. Thus, a feature that limited by “first”, “second” may expressly or implicitly include at least one of the features.

In the description of the present disclosure, the meaning of “plural” is two or more, unless otherwise specifically defined.

Throughout the specification and claims, when it is described that an element is “connected” to another element, the element may be “directly connected” to the other element, or “electrically connected” to the other element through a third element.

Furthermore, the term “comprising” will be understood as meaning the inclusion of elements but not the exclusion of any other elements, unless explicitly described to the contrary.

The following disclosure provides many different embodiments or examples to implement different structures of the present disclosure. In order to simplify the disclosure of the present disclosure, the components and settings of specific examples are described below. They are for example purposes only and are not intended to limit this application. Further, the present disclosure may repeat reference numbers and/or reference letters in different examples, such duplication is for the purpose of simplification and clarity, and does not by itself indicate the relationship between the various embodiments and/or settings discussed. Further, the present disclosure provides various examples of specific processes and materials, but those of ordinary skill in the art may be aware of the application of other processes and/or the use of other materials. The following are described in detail, it should be noted that the order of description of the following embodiments is not used as a qualification for the preferred order of embodiments.

Please refer to FIG. 1-FIG. 5, an embodiment of the present disclosure provides a chip-on-film, which comprises a flexible substrate 10, a positive polarity pin 30 and a plurality of negative polarity pins 20.

The flexible substrate 10 comprises a bendable film for arranging connection lines. Exemplarily, the flexible substrate 10 can be made of polyimide or polyester film or the like.

In the embodiment of the present disclosure, as shown in FIG. 1, the chip-on film may further comprise a driving chip 40. The driving chip 40 can be bonded on the flexible substrate 10 by pressing. The chip-on-film is rectangular in shape. The first direction X is the horizontal direction of the chip-of-film.

The plurality of negative polarity pins 20 are arranged on the flexible substrate 10. The plurality of negative polarity pins 20 are arranged in a row along the first direction X, and two adjacent negative polarity pins 20 are arranged at an interval. For example, the distance between two adjacent negative polarity pins 20 may be 0.12 mm±0.2 mm. The shape of each negative polarity pin 20 can be the same as the shapes of the other negative polarity pins 20. For example, all of the negative polarity pins 20 have a rectangular structure, and the negative polarity pins 20 extend along the second direction Y. That is, the first direction X is the short-side direction of the negative polarity pins 20, and the second direction Y is the long-side direction of the negative polarity pins 20. For example, each of the negative polarity pins 20 of the embodiment of the present disclosure has a rectangular structure of 0.13 mm×0.7 mm.

The negative polarity pins 20 and the positive polarity pin 30 can be made of metal materials, specifically copper, silver, another metal or their alloys. The material of the negative polarity pins 20 can be the same or different from the material of the positive polarity pin 30.

The positive polarity pin 30 is arranged on the flexible substrate 10. The positive polarity pin 30 is at least partly located between two adjacent negative polarity pins 20. The positive polarity pin 30 comprises a first extension portion 31 and a second extension portion 32. The first extension portion 31 intersects the second extension portion 32.

Both the first extension portion 31 and the second extension portion 32 may be rectangular. The first extension portion 31 and the second extension portion 32 extend in different directions respectively, and the first extension portion 31 interests the second extension portion 32, thereby facilitating the processing of the positive polarity pin 30. For example, the positive polarity pin 30 can be in the shape of “X”, “7” or a cross, so as to increase the difference between the shape of the positive polarity pin 30 and the shapes of the negative polarity pins 20, thereby improving the recognition accuracy of the CCD lens to the positive polarity pin 30 during bonding.

In other embodiments, the first extension portion 31 and the second extension portion 32 can be in other regular shapes (such as a triangular shape, a prismatic shape, a circular shape, a ring shape, and a wave shape) or irregular shapes. The shapes of the first extension portion 31 may be the same or different from the shapes of the second extension portion. The present applicant does not intend to limit the specific shape of the positive polarity pin 30.

The chip-on-film of the embodiment of the present disclosure is provided with a plurality of negative polarity pins 20 arranged in a row along the first direction X on the flexible substrate 10 and further with a positive polarity pin 30, wherein the positive polarity pin 30 is at least partially located between two adjacent negative polarity pins 20, and the positive polarity pin 30 comprises a first extension portion 31 and a second extension portion 32. The first extension portion 31 intersects the second extension portion 32, so as to increase the difference between the shape of the positive polarity pin 30 and the shapes of the negative polarity pins 20, thereby improving the recognition accuracy to the positive polarity pin 30. Accordingly, the alignment accuracy of the chip-on-film is improved, thereby preventing the short-circuit problem during bonding of the chip-on-film, which is conducive to improving the bonding yield of the chip-on-film.

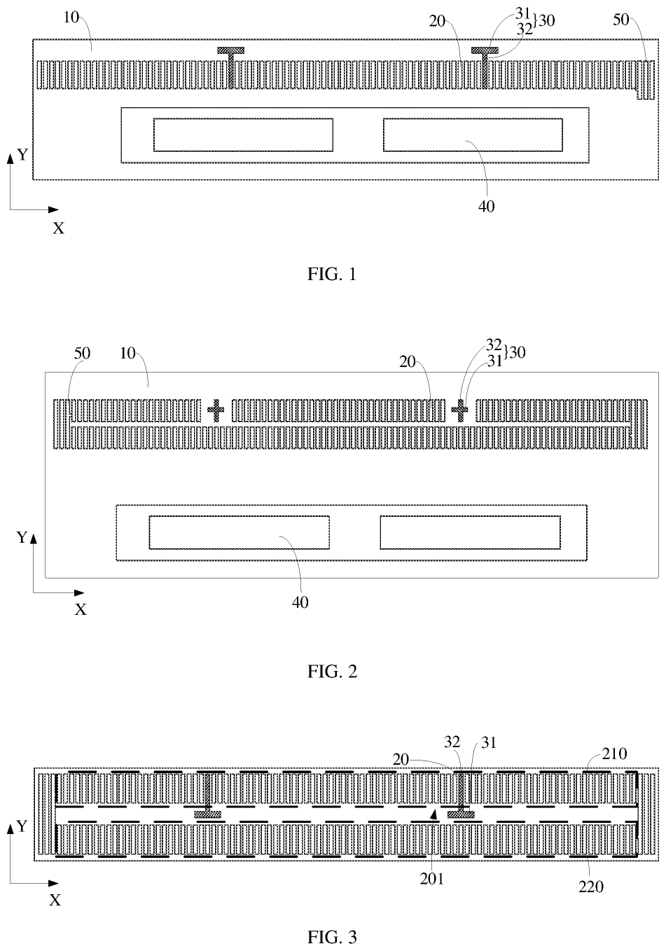

In some embodiments, as shown in FIG. 1 and FIG. 2, the first extension portion 31 extends along the first direction X, and the second extension portion 32 extends along the second direction Y. The first direction X and the second direction Y are the directions perpendicular to each other. For example, the first direction X is a horizontal direction, and the second direction Y is a vertical direction.

In the present disclosure, the term “perpendicular” refers to a state where the angle formed by two straight lines is greater 80° and less than 100°, therefore the state where this angle is greater 85° and less than 95° is included.

In the embodiment of the present disclosure, it is taken as an example that the negative polarity pins 20, the first extension potion 31, and the second extension potion 32 are all rectangular. The first extension portion 31 extends along the first direction X, and the negative polarity pins 20 and the second extension portion 32 both extend along the second direction Y, that is, the positive polarity pin 30 can be in a “+” shape, a “T” shape, or an “L” shape. Therefore, the difference between the shape of the positive polarity pin 30 and the shapes of the negative polarity pins 20 is increased, thereby improving the recognition accuracy of the positive polarity pin 30 while reducing the processing difficulty of the positive polarity pin 30, which is conducive to improving the production efficiency of the chip-on-chip film and saving the production cost.

In the embodiment of the present disclosure, each of the number of first extension portions 31 and the number of second extension portions 32 in each positive polarity pin 30 may be one or more. For example, each positive polarity pin 30 includes two first extension portions arranged in parallel and one second extension perpendicularly connected to the two first extension portions. For example, the positive polarity pin 30 can be in an “H” shape. The present disclosure does not intend to limit the number of first extension portions 31 and the number of second extension portions 32.

In some embodiments, the length of the first extension portion 31 ranges from 0.5 mm to 5 mm, and the length of the second extension portion 32 ranges from 0.7 mm to 1.5 mm. Taking the first extension portion 31 and the second extension portion 32 that have rectangular structures as an example, the length of the first extension portion 31 is less than the length of the second extension portion 32. The length of the first extension portion 31 may be 0.5 mm, and the length of the second extension portion 32 may be 0.8 mm.

In some embodiments, the first extension portion 31 is connected to one terminal of the second extension portion 32. Taking the first extension portion 31 and the second extension portion 32 that have rectangular structure as an example, the first extension portion 31 can be connected to one of the two opposite terminals of the second extension portion 32. The positive polarity pin 30 of the embodiment of the present disclosure can be in a “T” shape or an inverted “T” shape.

In some embodiments, as shown in FIG. 3, a plurality of negative polarity pins 20 are arranged in several rows. In the embodiment of the present disclosure, the plurality of negative polarity pins 20 are arranged in two rows, specifically comprising a first pin row 210 and a second pin row 220. Each pin row comprises two or more than two negative polarity pins 20, and the plurality of negative polarity pins 20 are arranged in two adjacent rows along the first direction X in the first pin row 210 and the second pin row 220 respectively, that is, the negative polarity pins 20 in the first pin row 210 and the negative polarity pins 20 in the second pin row 220 are arranged in rows respectively. The first pin row 210 and the second pin row 220 are arranged at an interval in the second direction Y, and the first pin row 210 and the second pin row 220 are arranged in parallel. For example, it is taken that the chip-on-film is provided with two rows of pins extending along the first direction X and arranged at an interval in the second direction Y. The first pin row 210 is closer to the central area of the chip-on-film, and the second pin row 220 is closer to the edge area of the chip-on-film.

In other embodiments, three or more pin rows may be provided as required. The embodiment of the present disclosure does not specifically limit the number of pin rows.

As shown in FIG. 1 and FIG. 3, the chip-on-film also comprises a plurality of signal input pins 50 arranged on the flexible substrate 10. The signal input pins 50 are used to transmit driving signals. The signal input pins 50 are arranged on the terminal portion of the chip-on-film. One signal input pin 50 is connected to one negative polarity pin 20 in the first pin row 210, and one signal input pin 50 is connected to one negative polarity pin 20 in the second pin row 220. For example, the total number of negative polarity pins 20, positive polarity pin 30 and signal input pins 50 in each chip-on-film is 444.

Please refer to FIG. 3, the negative polarity pins in two adjacent rows are arranged at an interval to form an accommodation area 201. The first extension portion 31 is in the accommodation area 201, and the second extension portion 32 is located between two adjacent negative polarity pins 20. The first pin row 210 and the second pin row 220 form the accommodation area 201 in the second direction Y, that is, the first extension portion 31 is located between the first pin row 210 and the second pin row 220. In the embodiment of the present disclosure, the distance between the first pin row 210 and the second pin row 221 in the second direction Y may be greater than 0.7 mm so that the space of the accommodation area 201 in the second direction Y may become larger, thereby prevents the second extension portion 32 from being short-circuited with the adjacent negative polarity pins 20 when the first extension portion 31 is located in the accommodation area 201, which improves the production yield of the chip-on-film.

In the embodiment of the present disclosure, the shape of the second extension portion 32 may be the same as the shapes of the negative polarity pins. By disposing the first extension portion 31 in the accommodation area 201 between the negative polarity pins 20 in two adjacent rows, the positive polarity pin 30 is in an inverted “T” shape. Therefore, in the cases where the distance between the second extension portion 32 and the negative polarity pins 20 remains unchanged, the difference between the shape the positive polarity pin 30 and the shapes of the negative polarity pins 20 is increased through the first extension portion, thereby increasing the recognition of the positive polarity pin 30.

In some embodiments, there are at least two positive polarity pins 30, and two positive polarity pins 30 are arranged at an interval. Each positive polarity pin 30 is located between two adjacent negative polarity pins 20.

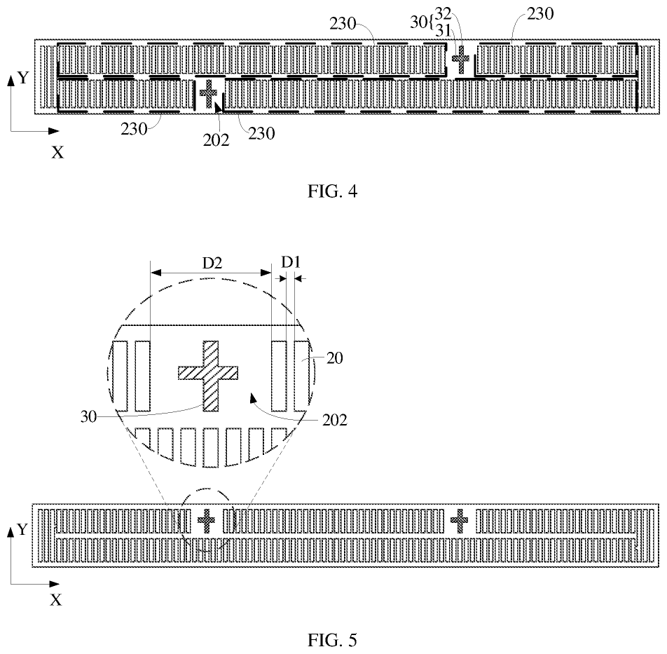

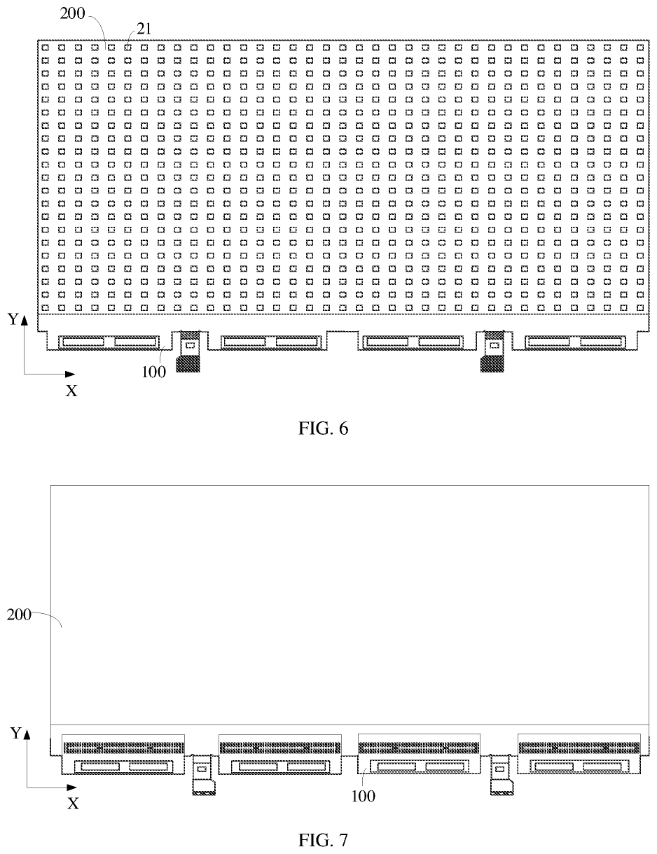

Taking the number of positive polarity pins being two as an example, as shown in FIG. 3, the two positive polarity pins 30 may be located between the negative polarity pins 20 in the same row. For example, two positive polarity pins 30 30 are arranged at an interval in the first pin row 210. Alternatively, as shown in FIG. 4, one positive polarity pin 30 is arranged in the first pin row 210, and one positive polarity pin 30 is arranged in the second pin row 220. The positive polarity pin 30 in the first pin row 210 and the positive polarity pin 30 in the second pin row 20 are arranged at an interval in the first direction X.

The number of positive polarity pins 30 may be set to one. For example, the positive polarity pin 30 can be located between two adjacent negative polarity pins 20 in the first pin row 210, however, the embodiments of the present disclosure are not limited thereto.

As shown in FIG. 5 and FIG. 4, the chip-on-film comprises two pin groups 230 arranged at an interval along the first direction X, and each pin group 230 comprises a plurality of negative polarity pins 20. Two adjacent negative polarity pins 20 are arranged at an interval along the first direction X to form a gap space 202.

The positive polarity pin 30 is at least partially located in the gap space 202 between two adjacent pin groups 230. The second extension portion 32 is located between two adjacent pin groups 230. The first extension portion 31 is located between two adjacent pin groups 230 or located above or below two adjacent pin groups 230.

In the first direction X, the distance between two adjacent negative polarity pins 20 in each pin group 230 is smaller than the distance between two pin groups 230. That is, in the first direction X, the distance between the center of the positive polarity 30 and the center of any negative polarity pin 20 adjacent to the positive polarity 30 is greater than the distance between the centers of two adjacent negative polarity pins 20. For example, the distance D1 between two adjacent negative polarity pins 20 in each pin group 230 can be 0.12 mm±0.2 mm, and the distance D2 between two pin groups 230 can range from 0.5 mm to 5 mm, that is, the length of the gap space 202 in the first direction X ranges from 0.5 mm to 5 mm.

In the embodiment of the present disclosure, the distance between two adjacent negative polarity pins 20 in each pin group 230 is less than the distance between the two pin groups 230, and the positive polarity pin 30 is arranged in the gap space 230 with a larger size between the two adjacent pin groups 230 so that the distance between the negative polarity pins 20 and the positive polarity pin 30 can be increased, which is beneficial to prevent the short circuit between the positive polarity pin 30 and the negative polarity pins 20 due to alignment errors during bonding. In addition, the positive polarity pin 30 can be identified through distance difference positioning by increasing the distance between the negative polarity pins 20 and the positive polarity pin 30 is increased, which is beneficial to further increase the recognition of the positive polarity pin 30 to further improve the flip chip. Thus, the alignment accuracy of the chip-on-film is further improved, which is conducive to improving the bonding yield of the chip-on-film.

In some embodiments, please refer to FIG. 5, both the first extension portion 31 and the second extension portion 32 are located between two adjacent negative polarity pins 20. Both the first extension portion 31 and the second extension portion 32 are located between two adjacent pin groups 230, that is, all the portions of the positive polarity pins 30 are located between two adjacent pin groups 230. In the embodiment of the present disclosure, through completely placing the positive polarity pin 30 between two adjacent pin groups 230, the recognition of the positive polarity pin 30 is increased by the distance difference. In this case, the space in the second direction Y of the chip-on-film, which is occupied by the first extension portion 31 when the first extension portion 31 is formed above or below the negative polarity pins 30, can be prevented from being increased, which, which is beneficial to increase the space utilization of the chip-on-film and accomplish the narrowing of the chip-on-film.

The middle portion of the first extension portion 31 of the positive polarity pin 30 is connected to the middle portion of the second extension portion 32 thereof, that is, the first extension portion 31 intersect the second extension portion 32 of the positive polarity pin 30 in the embodiment of the present disclosure c on the middle portions of the first extension portion 31 and the second extension portion 32. Taking the first extension portion 31 and the second extension portion 32 having rectangular structures as an example, the positive polarity pin 30 in the embodiment of the present disclosure may be in a “+” shape. In the embodiment of the present disclosure, through connecting the middle portion of the first extension portion 31 to the middle portion of the second extension portion 32, the length of the second extension portion 32 can be ensured so that the gap space 202 between two adjacent pin groups 230 can be fully utilized to form a positive polarity pin 30 that can be recognized more easily, which is beneficial to improve the alignment accuracy of the bonding of the chip-on-film.

An embodiment of the present disclosure provides a display device, comprising a light-emitting substrate 200 and the chip-on-film 100 of any one of the above-mentioned embodiments. One terminal of the chip-on-film 100 is bonded to the light-emitting substrate 200. Since the display device comprises the chip-on-film 100, it has all the same beneficial effects, which will not be repeated in this embodiment.

The light-emitting substrate 200 may be applied to the above-mentioned display device as a backlight unit, or may be used alone as a substrate having a display function or a light-emitting function, however, the embodiments of the present disclosure are not limited thereto. For example, taking a display device in which the light-emitting substrate 200 adopts light-emitting diodes 21 (LED) as an example, the light-emitting diodes 21 may be mini light-emitting diode (Mini-LEDs or micro light-emitting diodes (Micro-LEDs). Since the Mini-LEDs or Micro-LEDs have the characteristics of small size and high brightness, the larger number of Mini-LEDs or Micro-LEDs can be used in a backlight module of a display device, and the backlight can be finely adjusted to realize the display of high dynamic range (HDR) images. Mini-LEDs and Micro-LEDs can also be directly used as pixels in a display panel of a display device for display.

The embodiment of the present disclosure does not make specific restrictions on the application of the display device, which may be a handheld device (smart phone, tablet computer), wearable device (smart bracelet, wireless headset, smart watch, smart glasses), vehicle device (navigation system, auxiliary reversing system, driving recorder, car refrigerator, etc.), virtual reality device, augmented reality device, terminal device, etc., there is no restriction herein.

In the above embodiments, the description of each embodiment has its own emphasis, and the part not described in detail in one embodiment may refer to the relevant description of other embodiments. In the specific embodiment, the above units or structures may be implemented as independent entities, or in any combination, as the same or several entities to achieve, the specific implementation of the above units or structures may refer to the previous method embodiment, not repeated herein.

The above is a display device provided by an embodiment of the present disclosure is described in detail, and a specific example is applied herein to explain the principle and embodiment of the present disclosure, and the description of the above embodiment is only used to help understand the method of the present disclosure and its core ideas. At the same time, for those skilled in the art, according to the idea of the present disclosure, there will be changes in the specific embodiment and the scope of application, in summary, the content of this specification should not be understood as a restriction on the present disclosure.

What is claimed is:

1. A chip-on-film comprising:
a flexible substrate;
a plurality of negative polarity pins arranged in a row in a first direction on the flexible substrate, and two adjacent negative polarity pins of the plurality of negative polarity pins arranged in an interval; and
a positive polarity pin disposed on the flexible substrate, the positive polarity pin being at least partially located between two adjacent negative polarity pins of the plurality of negative polarity pins, the positive polarity pin comprising a first extension portion and a second extension portion, the first extension portion intersects the second extension portion.

2. The chip-on-film as claimed in claim 1, wherein the first extension portion extends in the first direction, the second extension portion extends in a second direction, and the first direction is perpendicular to the second direction.

3. The chip-on-film as claimed in claim 2, further comprising two pin groups disposed along the first direction at an interval, each of the pin groups comprises multiple negative polarity pins of the plurality of negative polarity pins, and two adjacent negative polarity pins in each pin group are disposed along the first direction at an interval,
wherein the positive polarity pin is at least partially located between the two pin groups that are adjacent to each other, and in the first direction, a distance between two adjacent negative polarity pins of the plurality of negative polarity pins is less than a distance between the two pin groups.

4. The chip-on-film as claimed in claim 3, wherein both the first extension portion and the second extension portion are located between two adjacent negative polarity pins of the plurality of negative polarity pins.

5. The chip-on-film as claimed in claim 4, wherein a middle portion of the first extension portion is connected with a middle portion of the second extension portion.

6. The chip-on-film as claimed in claim 2, wherein the first extension portion is connected to one terminal of the second extension portion.

7. The chip-on-film as claimed in claim 6, wherein the plurality of negative polarity pins are arranged in a plurality of rows, and the negative polarity pins in two adjacent rows of the plurality of rows are arranged at an interval to form an accommodation area, and
wherein the first extension portion is located in the accommodation area, and the second extension is located between two adjacent negative polarity pins of the plurality of negative polarity pins.

8. The chip-on-film as claimed in claim 1, wherein the number of positive polarity pins is at least two, the two positive polarity pins are disposed at an interval, each of the positive polarity pins is located between two adjacent negative polarity pins of the plurality of negative polarity pins.

9. The chip-on-film as claimed in claim 1, wherein a length of the first extension portion ranges from 0.5 mm to 5 mm, and a length of the second extension portion ranges from 0.7 mm to 1.5 mm.

10. A display device comprising:
a light-emitting substrate; and
a chip-on-film, one terminal of the chip-on-film is bonded to the light-emitting substrate, the chip-on-film comprising:
a flexible substrate;
a plurality of negative polarity pins arranged in a row in a first direction on the flexible substrate, and two adjacent negative polarity pins of the plurality of negative polarity pins arranged in an interval; and
a positive polarity pin disposed on the flexible substrate, the positive polarity pin being at least partially located between two adjacent negative polarity pins of the plurality of negative polarity pins, the positive polarity pin comprising a first extension portion and a second extension portion, the first extension portion intersects the second extension portion.

11. The display device as claimed in claim 10, wherein the first extension portion extends in the first direction, the second extension portion extends in a second direction, and the first direction is perpendicular to the second direction.

12. The display device as claimed in claim 11, wherein the chip-on-film further comprises two pin groups disposed along the first direction at an interval, each of the pin groups comprises multiple negative polarity pins of the plurality of negative polarity pins, and two adjacent negative polarity pins in each pin group are disposed along the first direction at an interval,
wherein the positive polarity pin is at least partially located between the two pin groups that are adjacent to each other, and in the first direction, a distance between two adjacent negative polarity pins of the plurality of negative polarity pins is less than a distance between the two pin groups.

13. The display device as claimed in claim 12, wherein both the first extension portion and the second extension portion are located between two adjacent negative polarity pins of the plurality of negative polarity pins.

14. The display device as claimed in claim 13, wherein a middle portion of the first extension portion is connected with a middle portion of the second extension portion.

15. The display device as claimed in claim 11, wherein the first extension portion is connected to one terminal of the second extension portion.

16. The display device as claimed in claim 15, wherein the plurality of negative polarity pins are arranged in a plurality of rows, and the negative polarity pins in two adjacent rows of the plurality of rows are arranged at an interval to form an accommodation area, and
wherein the first extension portion is located in the accommodation area, and the second extension is located between two adjacent negative polarity pins of the plurality of negative polarity pins.

17. The display device as claimed in claim 10, wherein the number of positive polarity pins is at least two, the two positive polarity pins are disposed at an interval, each of the positive polarity pins is located between two adjacent negative polarity pins of the plurality of negative polarity pins.

18. The display device as claimed in claim 10, wherein a length of the first extension portion ranges from 0.5 mm to 5 mm, and a length of the second extension portion ranges from 0.7 mm to 1.5 mm.

19. A chip-on-film comprising:
a flexible substrate;
a plurality of negative polarity pins, arranged in a row in a first direction on the flexible substrate, each of the plurality of negative polarity pins extending in a second direction; and
a positive polarity pin, disposed on the flexible substrate and located between two negative polarity pins of the plurality of negative polarity pins, a shape of the positive polarity pin is different from a shape of the negative polarity.

20. The chip-on-film as claimed in claim 19, wherein the positive polarity pin comprises a first extension portion extends in the first direction and a second extension portion extends in the second direction perpendicular to the first direction.
